(19) United States
(12) Patent Application Publication
(10) Pub. No.: US 2009/0102550 A1
(43) Pub. Date: Apr. 23, 2009

(54) AUDIO SIGNAL AMPLIFIER CIRCUIT WITH A MUTE FUNCTION

(75) Inventors: Shigeji Ohama, Kyoto (JP); Satoshi Oishi, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/917,113

(22) PCT Filed: Jun. 6, 2006
(86) PCT No.: PCT/JP2006/311266

§ 371 Date: Dec. 10, 2007

(30) Foreign Application Priority Data
Jun. 10, 2005 (JP) 2005-171452

(51) Int. Cl. H03F 3/38

(52) U.S. Cl. 330/10

(57) ABSTRACT

An integrator generates analog voltage in a manner that in an active state a duty ratio of an output signal of an class D amplifier is brought close to a duty ratio defined by an analog audio signal. A first mute circuit forcibly turns on the class D amplifier in an active state. In an active state, A voltage-fixing circuit fixes an output terminal of the class D amplifier to a predetermined fixed potential of Vdd/2. A second mute circuit is provided between an output terminal of a filter and ground, and connects the output terminal of the filter to ground in an active state. A mute control unit controls the integrator, the first mute circuit, the voltage-fixing circuit and the second mute circuit, respectively. As a result, the noise at the time of start and stop can be optimally reduced.

### 1. FIELD OF THE INVENTION

The present invention relates to an audio signal amplifier circuit, and it particularly relates to a noise reduction technology of a class D amplifier that amplifies pulse-width modulated signals.

### 2. DESCRIPTION OF THE RELATED ART

Along with the development of LSI technology in recent years, 1-bit DAC (Digital Analog Converter) is used to process the digital signals and amplify them in the digital audio equipment represented by CD players, MD players and the like. In this 1-bit DAC, the audio signals undergo a noise shaping by a ΔΣ modulator and are outputted as the 1-bit PWM signals which have been subjected to the pulse-width modulation (PWM).

A class D amplifier achieving the high efficiency is used to amplify this 1-bit PWM signals up to a predetermined level in order to drive a speaker which is a load. The amplified 1-bit PWM signals are converted into analog reproduction signals through a post low-pass filter so as to be produced as audio from the speaker. A driver circuit that amplifiers digital audio signals using a class D amplifier is disclosed in Patent Document 1, for example.

In such a class D amplifier, the noise due to the sudden change in the output signal of the class D amplifier may occur at the start or stop thereof. In the light of this, as in a conventional technique in Patent Document 1, a mute circuit is added between the DC-blocking capacitor provided in the load circuit and the speaker, to prevent this noise. This mute circuit is turned on at the timing when the noise occurs and is then short-circuited to the ground potential so as to suppress the occurrence of noise.

### [Patent Document 1]

Japanese Patent Application Laid-Open No. 2001-223537.

### SUMMARY OF THE INVENTION

As described in Patent Document 1, however, it is difficult to completely eliminate the noise outputted from the speaker by the only on and off of the mute circuit.

Also, the mute circuit described in Patent Document 1 includes a transistor for muting. As a transistor for this use, a transistor such as a power transistor is required which has a certain degree of drive capacity. Hence, the increase in circuit area and the cost hike cannot be avoided.

The present invention has been made in view of these problems and a general purpose thereof is to provide an audio signal amplifier circuit realizing the reduction of noise, caused at the time of start and stop of a class D amplifier, as compared with the conventional practice.

In order to solve the above problems, an audio signal amplifier circuit, according to an embodiment of the present invention, comprises: a class D amplifier; an integrator which receives the analog audio signal and an output signal of the class D amplifier and which generates analog voltage in a manner that in an active state a duty ratio of the output signal of said class D amplifier is brought close to a duty ratio defined by the analog audio signal; a pulse-width modulator which converts the analog voltage outputted from the integrator into a pulse-width modulation signal; a driver circuit which drives said class D amplifier, based on the pulse-width modulation signal; a first mute circuit, provided on a path leading to the class D amplifier from said pulse-width modulator, which forcibly turns off said class D amplifier in an active state; a voltage-fixing circuit which fixes the analog voltage outputted from the integrator in an active state, to a predetermined fixed potential; a filter which removes a high-frequency component of the output signal of the class D amplifier; a second mute circuit, provided between an output terminal of the filter and ground, which connects the output terminal of the filter to ground in an active state; and a mute control unit which controls the integrator, the first mute circuit, the voltage-fixing circuit and the second mute circuit, respectively.

According to this embodiment, the active and inactive can be switched independently for the integrator, the first mute circuit, the voltage-fixing circuit and the second mute circuit. Thus, the generation of noise from such an audio output unit as a speaker provided posterior to the filter can be optimally prevented at the time of start or stop of the audio signal amplifier circuit.

When the audio signal amplifier circuit is started, in a first stage the mute control unit may set the first mute circuit and the second mute circuit active, set the voltage-fixing circuit active and set the integrator inactive so as to be set the audio signal amplifier circuit to a mute state. Subsequently, in a second stage, the mute control unit may set the first mute circuit inactive, then set the voltage-fixing circuit inactive, set the integrator active and then set the second mute circuit inactive so as to terminate the mute state.

In the first stage where an initial state is set, the first and the second mute circuit are set active and, under this state, the voltage-fixing circuit is set active. This makes it possible to raise the voltage at the output terminal of the class D amplifier up to a predetermined DC level without the generation of noise from an audio output unit connected posterior to the filter. In the first stage, the mute control unit may set simultaneously the first mute circuit and the second mute circuit active. In the second stage, the duty ratio of pulse-width modulation signal outputted from the class D amplifier is fixed to a constant value determined by a fixed voltage, by setting the first mute circuit active from this initial state. Then the integrator is set active and the voltage-fixing circuit is set inactive. In this case, the integrator generates the analog voltage so that the time averaged value of voltage at the output terminal of the class D amplifier is brought close to the voltage set by the voltage-fixing circuit, and sets the duty ratio of the pulse-width modulation signal outputted from the pulse-width modulator. Hence, the discontinuity in the voltage waveform can be suppressed. Thereafter, the second mute circuit is set inactive and a state is set where the audio can be outputted from the audio output unit connected posterior to the filter. Thus, the generation of noise from the audio output unit can be suppressed.

When the audio signal amplifier circuit is stopped, the mute control unit may set the second mute circuit active, then set the first mute circuit active, and then set the integrator inactive and set the voltage-fixing circuit active so as to be set the audio signal amplifier circuit to a mute state.

According to this embodiment, the second mute circuit is turned on, thereby fixing the voltage at the output terminal of the filter. This can prevent the audio from being outputted from an audio output unit connected posterior thereto. Then the first mute circuit is set active and the operation of the class D amplifier is stopped. Thus, the audio signal amplifier circuit can be stopped without generating the noise.

The voltage-fixing circuit and the integrator include integrally: an operational amplifier in which the analog audio signal is inputted to a first input terminal thereof via a first resistor and a reference voltage is applied to a second input terminal thereof; a capacitor provided between an output terminal of the operational amplifier and the first input terminal; a switch and a second resistor provided in series between the output of the operational amplifier and an output terminal of the class D amplifier; and a third resistor provided between a connection node of the switch and the second resistor and the first input terminal of the operational amplifier, wherein when the switch is being on, the voltage-fixing circuit and the integrator function as the voltage-fixing circuit; and when the switch is being off, the voltage-fixing circuit and the integrator function as the integrator.

In this case, the circuitry can be simplified.

The audio signal amplifier circuit may further comprise: a fourth resistor provided between the output of the class D amplifier and the power supply line; and a fifth resistor provided between the output terminal of the class D amplifier and ground.

In this case, at the rise and fall of the power supply of the audio signal amplifier circuit, the charging and discharging of the capacitors can be accomplished promptly via the fourth resistor and the fifth resistor. Hence, the setup time and shutdown time can be shortened.

The class D amplifier, the integrator, the pulse-width modulator, the driver circuit, the first mute circuit, the voltage-fixing circuit and the mute control unit may be integrated on a single semiconductor substrate, and the filter and the second mute circuit are provided external to the semiconductor substrate.

The second mute circuit may include: a first bipolar transistor in which an emitter is connected to the output terminal of the filter and a collector is grounded; and a second bipolar transistor in which a collector is connected to the output of the filter and an emitter is grounded, wherein active/inactive may be switched by base voltages of the first bipolar transistor and the second bipolar transistor.

The second mute circuit is so configured that the emitters and collectors of two bipolar transistors are connected in the opposite direction to each other. Thereby, at least one of bipolar transistors can be turned on. Thus, the potential at the output terminal of the filter can be fixed more stably in the active state.

The audio signal amplifier circuit may further comprise a variable gain amplifier, provided anterior to the integrator, which amplifiers the analog audio signal. The mute control unit may control gain of the variable gain amplifier.

The gain of the variable gain amplifier is controlled in synchronism with the above-described first mute circuit, second mute circuit, voltage-fixing circuit and the like, which can suppress more suitably the generation of noise from the audio output unit.

When said audio signal amplifier circuit is started, in a first stage the mute control unit may set the first mute circuit and the second mute circuit active, set the voltage-fixing circuit active and set the integrator inactive and sets the gain of said variable gain amplifier to a minimum value so as to be set to a mute state so as to be set the audio signal amplifier circuit to a mute state. Subsequently, in a second stage, the mute control unit may set the first mute circuit inactive, then set the voltage-fixing circuit inactive, set the integrator active, then set the second mute circuit inactive so as to terminate the mute state, and then may increase gradually the gain of the variable gain amplifier.

In this case, after it is once set to a mute state and the mute state is deactivated not to generate the noise, the gain of the variable gain amplifier is gradually increased. As a result, the sound volume increases gradually starting from a state of no sound. Hence, the noise can be suppressed more optimally. The provision of the variable gain amplifier allows the voltage at the output terminal of the filter to rise up slowly at power-on of the audio signal amplifier circuit. Thus, the size of transistors used for the second mute circuit can be made smaller.

When the audio signal amplifier circuit is stopped, the mute control unit may decrease gradually the gain of the variable gain amplifier to the minimum value, then turn the second mute circuit on, then set the first mute circuit active, and then may set the integrator inactive and set the voltage-fixing circuit active so as to be set the audio signal amplifier circuit to a mute state.

At the time of stop of the audio signal amplifier circuit, the amplitude of analog audio signal inputted to the pulse-width modulator is reduced, and then the control is performed on circuits starting from the second mute circuit. Thereby, the voltage at the output terminal of the filter falls slowly, so that the size of transistors used for the second mute circuit can be made smaller.

Another embodiment of the present invention relates to an electronic apparatus. This electronic apparatus comprises: an audio reproduction unit which outputs an analog audio signal; an above-described audio signal amplifier circuit which amplifies the analog audio signal outputted from the audio reproduction unit; and an audio output unit driven by the audio signal amplifier.

The audio output unit may be such a device as a speaker, an earphone and a headphone which converts electric signals to the vibration of air. This audio output unit needs not be constantly connected with the electronic apparatus and may be structured in a detachable manner.

According to this embodiment, the generation of noise from the audio output unit can be prevented at the time of power-on and power-off of the electronic apparatus.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing a structure of an audio signal amplifier circuit according to an embodiment of the present invention.

FIG. 2 is a block diagram showing a structure of an electronic apparatus equipped with an audio signal amplifier circuit of FIG. 1;

FIG. 3 is a circuit diagram showing an example of the structure of a second mute circuit.

FIG. 4 is a time chart showing operating states of the audio signal amplifier circuit of FIG. 1 at the time of start and stop.

FIG. 5 is a circuit diagram showing a modification of an integrator.

### DETAILED DESCRIPTION OF THE INVENTION

The present invention will be described hereinbelow based on preferred embodiments, with reference to Figures. The components, members and processings identical to or equivalent to those shown in each Figure are given the same reference numerals, and the repeated explanation thereof is omitted as appropriate. The embodiments do not intend to limit the present invention but exemplify the invention. And all of the features and the combinations thereof described in the embodiments are not necessarily essential to the invention.

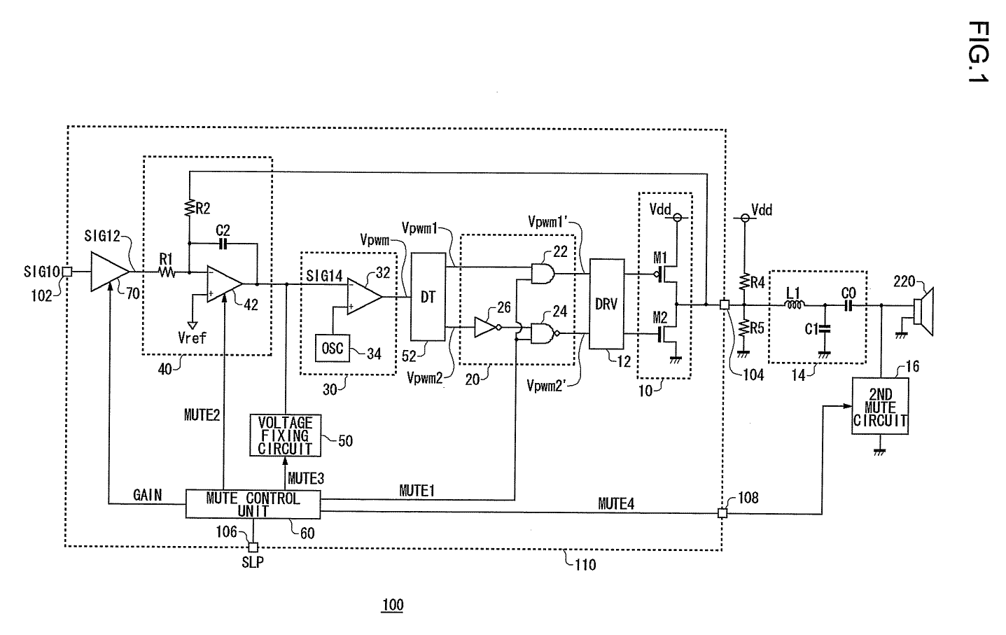

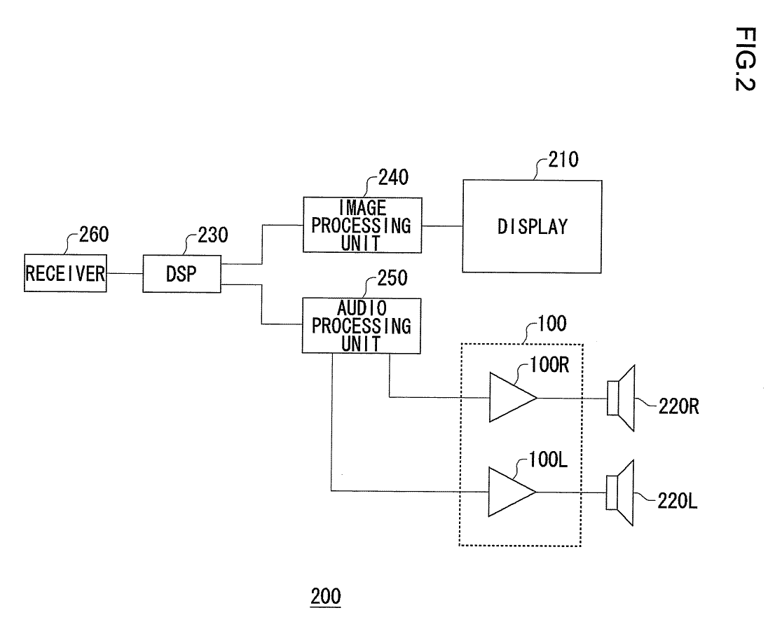

FIG. 1 is a circuit diagram showing a structure of an audio signal amplifier circuit 100 according to an embodiment of the present invention. FIG. 2 is a block diagram showing a structure of an electronic apparatus 200 equipped with an audio signal amplifier circuit 100 of FIG. 1. In the present embodiment, the electronic apparatus 200 is a television set. The electronic apparatus 200 includes a display 210 such as a Braun tube and a liquid crystal panel, speakers 220R, 220L, a DSP (Digital Signal Processor) 230, an image processing unit 240, an audio processing unit 250, an audio signal amplifier circuit 100 and a receiver 260.

The receiver 260 is a tuner or the like, and it detects the broadcast waves inputted from a not-shown antenna and amplifies them so as to be outputted to the DSP 230. The DSP 230 demodulates the signals outputted from the receiver 260, and outputs data on images to the image processing unit 240 and outputs data on audio to the audio processing unit 250, respectively. Also, the DSP 230 is a core block which controls the whole of the electronic apparatus 200 integrally. The image processing unit 240 includes a display driver and so forth, and performs signal processing necessary for the image data and displays the images and videos on the display 210 per scanning line. The receiver 260 may be a unit that receives signals from a VTR (Video Tape Recorder), DVD player or the like.

The audio processing unit 250 performs a predetermined signal processing on the audio signals outputted from the DSP 230 so as to be outputted to the audio signal amplifier circuit 100. In so doing, if the audio signal is a stereo signal, the audio signal is distributed to a right channel and a left channel. The audio signal amplifier circuit 100 includes two audio signal amplifier circuits 100R and 100L for use with the right channel and the left channel. The audio signal amplifier circuits 100R and 100L respectively amplify the audio signals and output them to the speakers 220R and 220L. The audio signal amplifier circuit 100 according to the present embodiment is mounted on such an electronic apparatus 200.

When such an electronic apparatus 200 is powered on by a user, the DSP 230 carries out the initialization processing. In so doing, the DSP 230 initializes each block, such as the image processing unit 240 and the audio signal amplifier circuit 100.

Refer back to FIG. 1. The audio signal amplifier circuit 100 includes an audio LSI 110 having a class D amplifier and the like incorporated therein, a filter 14, a second mute circuit 16, a fourth resistor R4 and a fifth resistor R5.

The audio LSI 110 is a semiconductor integrated circuit wherein an inputted analog audio signal SIG10 is converted to a pulse-width signal having a duty ratio in accordance with the amplitude of the analog audio signal SIG10 and then outputted. The audio LSI 110 is comprised of an input terminal 102, an output terminal 104, a sleep terminal 106 and a mute control terminal 108 as an input/output terminal. The analog audio signal SIG10 outputted from the audio processing unit 250 of FIG. 2 is inputted to the input terminal 102. The output terminal 104 is connected with the filter 14, and a switching voltage Vsw which has been pulse-width modulated is outputted therefrom. A sleep signal SLP is inputted to a sleep terminal 106 from outside. When the electronic apparatus 200 equipped with this audio LSI 110 is powered on, this sleep signal SLP goes high level. And when the power is shut off, it becomes low level.

The filter 14, which includes an inductor L1, a first capacitor C1 and an output capacitor Co, is a low-pass filter which removes high-frequency components of the switching voltage Vsw outputted from the audio LSI 110. The output capacitor Co is a DC-blocking capacitor by which to block the DC current from flowing into the speaker 220. The high-frequency components of the switching voltage Vsw outputted from the audio LSI 110 are removed by the filter 14, so that the pulse-width modulated signals are converted into analog audio signals.

The second mute circuit 16 is provided between the output terminal of the filter 14 and the ground. In this second mute circuit 16, a fourth mute signal MUTE4 outputted from the mute control terminal 108 of the audio LSI 110 allows the switching between the active and the inactive state, and the output terminal of the filter 14 is grounded in the active state. When the second mute circuit 16 becomes active, the voltage applied to the speaker 220 is fixed to the ground potential, so that the audio from the speaker 220 is muted.

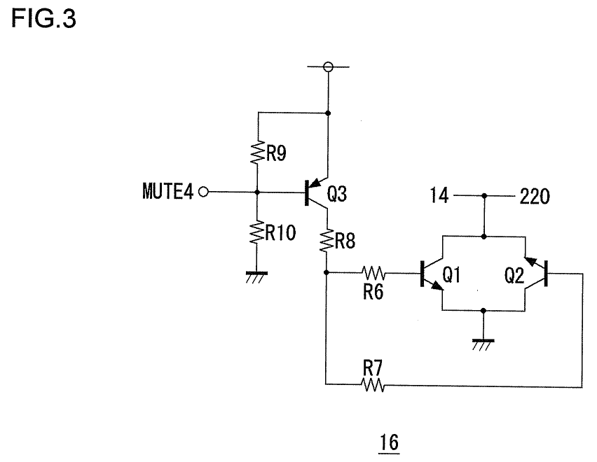

FIG. 3 is a circuit diagram showing an example of the structure of the second mute circuit 16. The second mute circuit 16 includes a first bipolar transistor Q1, a second bipolar transistor Q2, a third bipolar transistor Q3, a sixth resistor R6, a seventh resistor R7, an eighth resistor R8, a ninth resistor R9, and a tenth resistor R10. The collector of the first bipolar transistor Q1 of NPN type is connected to the output terminal of the filter 14 and the emitter thereof is connected to the ground. The emitter of the second bipolar transistor Q2 of NPN type is connected to the input terminal of the filter 14 and the collector thereof is connected to the ground. An inexpensive discrete transistor for use with small signals may be used as the first bipolar transistor Q1 and the second bipolar transistor Q2.

A supply voltage Vdd is applied to the emitter of the third bipolar transistor Q3 of PNP type, and one end of the eighth resistor R8 is connected with the collector thereof. The other end of the eighth resistor R8 is connected to the base of the first bipolar transistor Q1 and the base of the second bipolar transistor Q2 via the sixth resistor R6 and the seventh resistor R7, respectively. The third bipolar transistor Q3 is provided for supplying the base current to the first bipolar transistor Q1 and the second bipolar transistor Q2. The base of the third bipolar transistor Q3 is connected to the power supply line via the ninth resistor R9 and is also connected to the ground via the tenth resistor R10. A fourth mute signal MUTE4 is inputted to the base of the third bipolar transistor Q3.

In this second mute circuit 16, the base voltage of the first bipolar transistor Q1 and the second bipolar transistor Q2 is controlled by the fourth mute signal MUTE4. When the fourth mute signal MUTE4 is high level, the third bipolar transistor Q3 is turned off and the second mute circuit 16 becomes inactive. On the contrary, when the fourth mute signal MUTE4 is low level, the third bipolar transistor Q3 is turned on and the second mute circuit 16 becomes active. The two bipolar transistors Q1 and Q2 are connected in a manner such that the emitters and collectors thereof are connected the other way around and therefore at least one of the bipolar transistors can be turned on. Thereby, the potential of the output terminal of the filter 14 can be fixed more stably in an active state.

Note that the configuration of the second mute circuit 16 is not limited to the circuit shown in FIG. 3 and other types of circuitry may serve the purpose as long as the voltage at the output terminal of the filter 14, namely the input terminal of the speaker 220, can be fixed to the ground potential.

Reference is made back to FIG. 1. The output terminal 104 is connected to the power supply line via the fourth resistor R4 and is connected to the ground via the fifth resistor R5. The fourth resistor R4 and fifth resistor R5 function as a charge/discharge circuit for the first capacitor C1 and the output capacitor Co. The resistance values of the fourth resistor R4 and the fifth resistor R5 are set to the identical value.

Next, a description will be given of a structure of the audio LSI 110. The audio LSI 110 includes a class D amplifier 10, a driver circuit 12, a first mute circuit 20, a pulse-width modulator 30, an integrator 40, a voltage-fixing circuit 50, a mute control unit 60, and a variable gain amplifier 70.

An analog audio signal SIG10 inputted to the input terminal 102 is inputted to the variable gain amplifier 70. In this variable gain amplifier 70, the DC level is set to a midpoint between the supply voltage Vdd and the ground potential (hereinafter referred to as a midpoint level). When the gain is at the minimum value, the variable gain amplifier 70 outputs the DC voltage of Vdd/2. As the gain increases, it amplifies the analog audio signal SIG10 and outputs the signal adding to the midpoint level of Vdd/2. The output signal of the variable gain amplifier 70 is called an analog audio signal SIG12. The gain of the variable gain amplifier 70 is controlled by a gain control signal GAIN outputted from the mute control unit 60.

Also, an anti-aliasing filter (not shown) which removes the signals of the Nyquist frequency or above so as to prevent the aliasing noise is provided anterior to, posterior to, or integrally with the variable gain amplifier 70.

Not only the analog audio signal SIG12 is inputted to the integrator 40 from the variable gain amplifier 70, but also the switching voltage Vsw which is an output signal of the class D amplifier 10 is feedback-inputted to the integrator 40. This integrator 40 includes an operational amplifier 42, a first resistor R1, a second resistor R2 and a second capacitor C2.

The analog audio signal SIG12 is inputted to the inverting input terminal of the operational amplifier 42 via the first resistor R1, whereas a voltage Vdd/2, which is an midpoint level between the supply voltage Vdd and the ground potential, is inputted to the noninverting input terminal thereof as a reference voltage Vref. The second capacitor C2 is provided between the output terminal of the operational amplifier 42 and the inverting input terminal thereof. The second resistor R2 is provided between the output terminal of the class D amplifier 10, namely the output terminal 104, and the inverting input terminal of the operational amplifier 42.

This integrator 40 is so configured that the active or inactive is switchable by the second mute signal MUTE2 outputted from the mute control unit 60. The integrator 40 generates a analog voltage SIG14 in a such a manner that, in an active state, the duty ratio of the switching voltage Vsw is brought close to the duty ratio defined by the analog audio signal SIG12.

The pulse-width modulator 30 includes a comparator 32 and an oscillator 34, and converts the analog voltage SIG14 outputted from the integrator 40 into a pulse-width modulation signal Vpwm. The oscillator 34 produces a period voltage Vosc of triangular waves or sawtooth waves and then outputs it to the noninverting input terminal of the comparator 32. The comparator 32 compares this period voltage Vosc with a voltage level Vsig14 of analog voltage SIG14 inputted to the noninverting input terminal. If Vosc>Vsig14, it outputs high-level pulse-width modulation signal Vpwm; and if Vosc<Vsig14, it outputs low-level pulse-width modulation signal Vpwm. The duty ratio of this pulse-width modulation signal Vpwm varies in accordance with the analog audio signal SIG12.

The driver circuit 12 drives the class D amplifier 10, based on the pulse-width modulation signal Vpwm outputted from the pulse-width modulator 30. The class D amplifier 10 includes a first MOS transistor M1 of P channel and a second MOS transistor M2 of N channel which are connected in series between the power supply line and the ground. When the pulse-width modulation signal Vpwm is low level, the driver circuit 12 turns on the first MOS transistor M1 and turns off the second MOS transistor M2; and when the pulse-width modulation signal Vpwm is high level, it turns off the first MOS transistor M1 and turns on the second MOS transistor M2.

A dead time generator 52 generates a dead time during which both the first MOS transistor M1 and the second MOS transistor M2 are not turned on simultaneously. For example, the dead time generator 52 generates a logic-inverted first pulse-width modulation signal Vpwm1 by delaying a negative edge of the pulse-width modulation signal Vpwm by a predetermined time period, and a logic-inverted second pulse-width modulation signal Vpwm2 by delaying a positive edge of the pulse-width modulation signal Vpwm by a predetermined time period. Since any existing techniques may be used to generate the dead time, the explanation thereof is omitted.

The first mute circuit 20 is provided on a path leading from the pulse-width modulator 30 to the class D amplifier 10. This first mute circuit 20 is such that the active and the inactive state can be switched by a first mute signal MUTE1 outputted from the mute control unit 60.

The first mute circuit 20 includes an AND gate 22, a NAND gate 24 and an inverter 26. The AND gate 22 outputs an AND operation of the first pulse-width modulation signal Vpwm1 outputted from the dead time generator 52 and the first mute signal MUTE1. When the first mute signal MUTE1 is low level, a first pulse-width modulation signal Vpwm1′ outputted from the AND gate 22 is fixed to the low level; and when the first mute signal MUTE1 is high level, it becomes equal to the first pulse-width modulation signal Vpwm1.

The inverter inverts the second pulse-width modulation signal Vpwm2 outputted from the dead time generator 52. The NAND gate 24 outputs a NAND operation of an output signal of the inverter 26 and the first mute signal MUTE1. When the first mute signal MUTE1 is low level, a second pulse-width modulation signal Vpwm2′ outputted from the NAND gate 24 is fixed to the high level; and when the first mute signal MUTE1 is high level, it becomes a signal reflecting the logical value of the second pulse-width modulation signal Vpwm2.

In other words, when the first mute signal MUTE1 is low level, the first mute circuit 20 becomes active. And the first mute circuit 20 fixes the first pulse-width modulation signal Vpwm1′ outputted to the driver circuit 12, to the low level and the second pulse-width modulation signal Vpwm2′ to the high level, and then turns off the first MOS transistor M1 and the second MOS transistor M2 so as to forcibly turn off the class D amplifier 10.

The voltage-fixing circuit 50 is connected with the output terminal of the integrator 40. This voltage-fixing circuit 50 is such that the active and the inactive can be switched by a third mute signal MUTE3 outputted from the mute control unit 60 and in an active state the voltage at the output terminal of the integrator 40 is fixed to a predetermined fixed potential. According to the present embodiment, the predetermined fixed voltage is set to the midpoint level Vdd/2 between the supply voltage Vdd and the ground potential.

The mute control unit 60 generates the first mute signal MUTE1 to the fourth mute signal MUTE4, based on a sleep signal SLP inputted to the sleep terminal 106, and controls the integrator 40, the first mute circuit 20, the voltage-fixing circuit 50 and the second mute circuit 16, respectively.

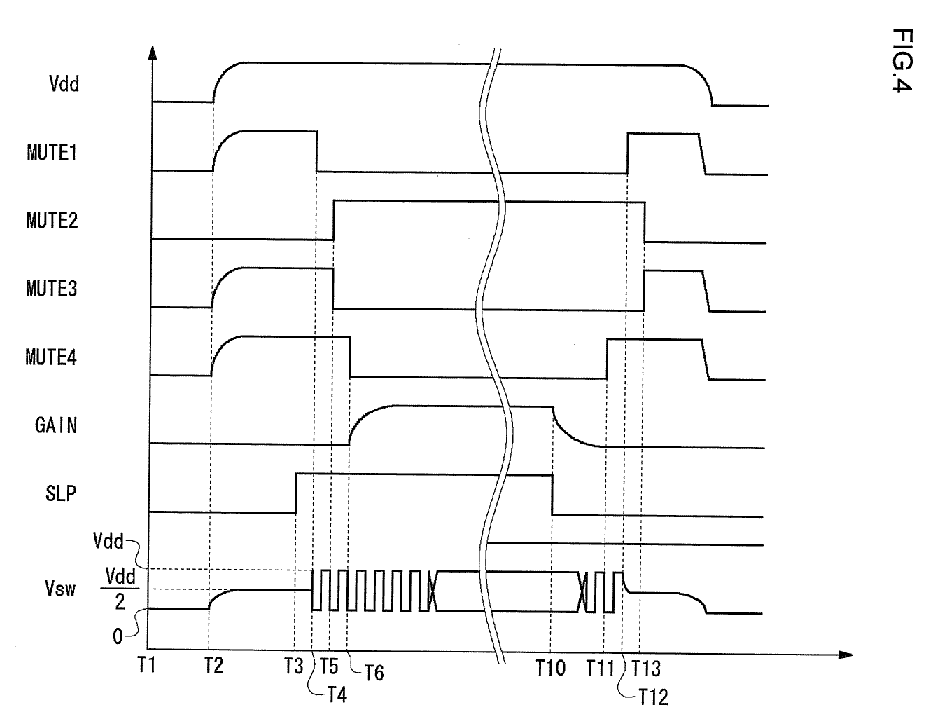

An operation of the audio signal amplifier circuit 100 configured as above will be described. FIG. 4 is a time chart showing operating states of the audio signal amplifier circuit 100 at the time of start and stop thereof. The vertical axis and the horizontal axis of FIG. 4 are shown differently from the actual scale for the purpose of clarity.

Firstly, a description is given of the operation of the audio signal amplifier circuit 100 at the time of start thereof.

At time T1, the power supply of an electronic apparatus 200 is at a stop. When the power-on of the electronic apparatus 200 is instructed from a user at time T2, a power supply apparatus inside the electronic apparatus 200 is activated and the supply voltage Vdd of the power supply line in the audio signal amplifier circuit 100 rises up. When the supply voltage Vdd rises up, the output capacitor Co and first capacitor C1 in the filter 14 are charged via the fourth resistor R4 and increase according to a CR time constant. As described above, the resistance value of the fourth resistor R4 is equal to that of the fifth resistor R5, so that the switching voltage Vsw at the output terminal 104 rises up to the midpoint Vdd/2 of the supply voltage Vdd and the ground potential.

When the supply voltage Vdd is supplied at time T2, the mute control unit 60 sets, as a first stage, the fourth mute signal MUTE4 to a high level and sets the second mute circuit 16 active. Further, the mute control unit 60 sets the first mute signal MUTE1 to a high level, sets the second mute signal MUTE2 to a low level, and sets the first mute circuit 20 and the voltage-fixing circuit 50 active, and at the same time sets the integrator 40 inactive. In this manner, the audio signal amplifier circuit 100 is set to a mute state. When the voltage-fixing circuit 50 becomes active, the voltage at the output terminal of the integrator 40, namely an analog voltage SIG14 inputted to the pulse-width modulator 30 is fixed to Vdd/2, too. As a result, the duty ratio of the pulse-width modulation signal Vpwm outputted from the pulse-width modulator 30 gets close to 50%.

At time T3 the sleep signal SLP inputted to the sleep terminal 106 becomes high level, the deactivation of the mute state is instructed. At time T4, the mute control unit 60 sets the first mute signal MUTE1 to a low level and sets the first mute circuit 20 inactive. As the first mute circuit 20 becomes inactive, the driver circuit 12 starts driving the class D amplifier 10, based on the pulse-width modulation signal Vpwm outputted from the pulse-width modulator 30. As a result, the switching voltage Vsw becomes a pulse-width modulation signal whose duty ratio is fixed to approximately 50%.

Subsequently, at time T5 the mute control unit 60 sets the second mute signal MUTE2 to a high level and the third mute signal MUTE3 a low level, sets the integrator 40 active and at the same time sets the voltage-fixing circuit 50 inactive. As the first mute circuit 20 becomes inactive and the integrator 40 becomes active, a feedback loop is formed where the switching voltage Vsw reaches the class D amplifier 10 from the integrator 40 via the dead time generator 52, the first mute circuit 20 and the driver circuit 12 and is again fed back to the integrator 40. A feedback control is performed using this feedback loop in a manner such that the duty ratio of the switching voltage Vsw, which is the output signal of the class D amplifier 10, is brought close to the duty ratio defined by the analog audio signal SIG12. Thereby, a deviation caused, in the duty ratio, due to the occurrence of offsets of the operational amplifier 42 is corrected, so that the duty ratio of 50% can be attained with accuracy.

The aforementioned feedback loop is formed at time T5 and the duty ratio of the switching voltage Vsw at the output terminal 104 is fixed to 50%. Subsequently, at time T6 the mute control unit 60 sets the fourth mute signal MUTE4 to a low level and sets the second mute circuit 16 inactive so as to deactivate the mute state.

Simultaneously at or after time T6, the mute control unit 60 increases gradually a gain GAIN of the variable gain amplifier 70. As a result, the sound volume of audio signals can be increased gradually without causing the speaker 220 to produce the unpleasant noise.

Next, a description is given of the operation of the audio signal amplifier circuit 100 at the time of stop thereof. At time T10, the sleep signal SLP becomes low-level and the transition to a mute state is instructed. Upon receipt of this instruction, the mute control unit 60 lowers gradually a gain GAIN of the variable gain amplifier 70. As the gain of the variable gain amplifier 70 becomes minimum, the analog audio signal SIG12 outputted from the variable gain amplifier 70 becomes a DC voltage of Vdd/2. As the analog audio signal SIG12 becomes Vdd/2, the duty ratio of the switching voltage Vsw is fixed to 50% by the feedback control performed by the integrator 40.

Then, at time T11 the mute control unit 60 sets the fourth mute signal MUTE4 to a high level, and prevents the generation of noise in a manner such that the input terminal of the speaker 220 is fixed to the ground potential while the second mute circuit 16 is being set active.

Then, at time T12 the mute control unit 60 sets the first mute signal MUTE1 to a high level and sets the first mute circuit 20 active. As the first mute circuit 20 becomes active, the switching operation of the class D amplifier 10 comes to a stop. When the switching operation of the class D amplifier 10 comes to a stop, the switching voltage Vsw occurring at the output terminal 104 is fixed to Vdd/2 by the fourth resistor R4 and the fifth resistor R5.

Then, at time T13 the second mute signal MUTE2 is set to a low level and the third mute signal MUTE3 is set to a high level. Then the integrator 40 is set inactive and at the same time the voltage-fixing circuit 50 is set active so as to be set the audio signal amplifier circuit 100 to a mute state. As the voltage-fixing circuit 50 becomes active, the switching voltage Vsw is fixed to Vdd/2 by the voltage-fixing circuit 50. Thereafter, the supply voltage Vdd applied to the power supply line drops. Thereby, all the first mute signal MUTE1 to the fourth mute signal MUTE4 become low-level and the electronic apparatus 200 comes to a stop.

According to the audio signal amplifier circuit 100 of the present embodiment, the active or inactive can be independently switched for the integrator 40, the first mute circuit 20, the voltage-fixing circuit 50 and the second mute circuit 16. Hence, the generation of noise from the speaker 220 provided posterior to the filter 14 can be optimally prevented at the time of start or stop of the audio signal amplifier circuit 100.

More specifically, when starting the audio signal amplifier circuit 100, the mute control unit 60 sets the second mute circuit 16 active as a first stage and, with this state, sets the voltage-fixing circuit 50 active.

Thereby, the voltage Vsw at the output terminal 104 of the class D amplifier can rise up to a predetermined DC level of Vdd/2 without the generation of noise from the speaker 220 connected posterior to the filter 14.

As a second stage, from this initial state the first mute circuit 20 is set active and then the integrator 40 is set active and at the same time the voltage-fixing circuit 50 is set inactive. At this time, the integrator 40 generates the analog voltage SIG14 so that the time averaged value of voltage Vsw at the output terminal 104 of the class D amplifier 10 is brought close to the voltage Vdd/2 set by the voltage-fixing circuit 50, and sets the duty ratio of the pulse-width modulation signal Vpwm outputted from the pulse-width modulator 30. Hence, the discontinuity in the voltage waveform can be suppressed. Thereafter, the second mute circuit 16 is set inactive and a state is set where the audio can be outputted from the speaker 220 connected posterior to the filter 14. Thus, the generation of noise from the speaker 220 can be suppressed.

When stopping the audio signal amplifier circuit 100, the mute control unit 60 turns the second mute circuit 16 on and thereby fixes the voltage at the output terminal of the filter 14 to the ground potential. Thus the output of audio from the speaker 220 connected posterior thereto can be prevented. Then the first mute circuit 20 is set active, stops the operation of the class D amplifier 10 and fixes, by the voltage-fixing circuit 50, the voltage Vsw at the output terminal 104 of the class D amplifier 10 to a predetermined value of Vdd/2. Thereby, the audio signal amplifier circuit 100 can be stopped without the generation of noise.

Further, the audio signal amplifier circuit 100 is comprised of the fourth resistor R4 provided between the output terminal 104 of the class D amplifier 10 and the power supply line, and the fifth resistor R5 provided between the output terminal 104 of the class D amplifier 10 and the ground. Thereby, at the rise and fall of the power supply of the audio signal amplifier circuit 100, the charging and discharging of the capacitors Co and C1 in the filter 14 can be accomplished promptly via the fourth resistor R4 and the fifth resistor R5. Hence, the setup time and shutdown time can be shortened.

Further, the audio signal amplifier circuit 100 is comprised of the variable gain amplifier 70, provided anterior to the integrator 40, which amplifies the analog audio signal SIG10. After setting the second mute circuit 16 inactive and terminating a mute state, the mute control unit 60 increases gradually the gain of this variable gain amplifier 70 at a power-on. As a result thereof, the noise generated from the speaker 220 can be suppressed. At a power-off, the mute control unit 60 lowers gradually the gain of this variable gain amplifier 70 to the minimum value, and then controls in the order starting from the second mute circuit 16. As a result, the voltage amplitude at the output terminal of the filter 14 becomes very small and therefore the size of a transistor used for the second mute circuit 16 can be made small.

The present invention has been described based on the embodiments. The embodiments are merely exemplary, and it is understood by those skilled in the art that various modifications to the combination of each component and process thereof are possible and that such modifications are also within the scope of the present invention. A description will be given of such modifications hereinbelow.

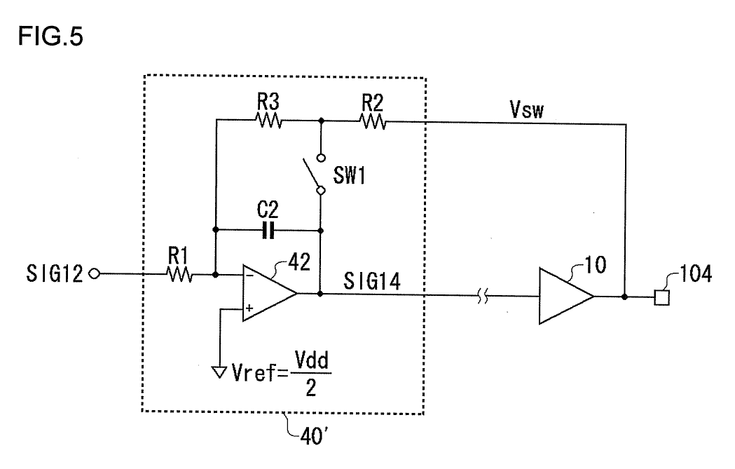

FIG. 5 is a circuit diagram showing a modification of the integrator 40. The configuration of an integrator 40′ of FIG. 5 is such that the integrator shown in FIG. 1 and the voltage-fixing circuit 50 are integrally structured.

The integrator 40′ includes an operational amplifier 42, a first resistor R1, a second resistor R2, a third resistor R3 and a second capacitor C2.

An analog audio signal SIG12 is inputted to the inverting input terminal of the operational amplifier 42 via the first resistor R1, whereas a midpoint of supply voltage and ground potential, namely a voltage of Vdd/2, is inputted to the noninverting input terminal as a reference voltage Vref. The second capacitor C2 is provided between the output terminal of the operational amplifier 42 and the noninverting input terminal. A switch SW1 and the second resistor R2 are connected in series between the output of the operational amplifier 42 and an output terminal 104 of a class D amplifier 10.

The third resistor R3 is provided between the connection node of the switch SW1 and the second resistor R2 and the inverting input terminal of the operational amplifier 42.

When the switch SW1 is turned on, an inverting amplifier is formed by the operational amplifier 42, the first resistor R1 and the third resistor R3. When the level of the analog audio signal SIG12 is Vdd/2, an analog voltage SIG14 outputted from the operational amplifier 42 becomes Vdd/2. The potential at the output terminal of the operational amplifier 42 and the potential at the output terminal 104 of the class D amplifier 10 connected via the second resistor R2 become each Vdd/2, too. That is, in an ON state of the switch SW1 this integrator 40′ functions as the voltage-fixing circuit 50 of FIG. 1.

When the switch SW1 is turned off, a voltage Vsw at the output terminal of the class D amplifier 10 is fed back to the inverting terminal of the operational amplifier 42 via the third resistor R3. In a state where the first mute circuit 20 of FIG. 1 is inactive, a switching voltage Vsw whose pulse-width has been modulated occurs at the output terminal 104. This switching voltage Vsw is fed back via the second resistor R2 and the third resistor R3 and then smoothed by the second capacitor C2. The integrator 40′ produces an analog voltage SIG14 in such a manner that the duty ratio of the switching voltage Vsw is brought close to the duty ratio defined by the analog audio signal SIG12.

In other words, in an OFF state of the switch SW1 the integrator 40′ functions as the integrator 40 of FIG. 1.

According to the integrator 40′ of FIG. 5, the on and off of the switch SW1 is controlled by the mute control unit 60, so that whether the function of an integrator or voltage-fixing circuit is to be made active can be switched.

In the embodiment, a description was given of a case where the variable gain amplifier 70 is provided anterior to the integrator 40, the gain of the variable gain amplifier 70 is controlled in synchronism with the first mute circuit 20, the driver circuit 12 and the like at the start and stop of the audio signal amplifier circuit 100, but the embodiment is not limited thereto.

For example, the variable gain amplifier 70 may be provided external to the audio signal amplifier circuit 100. In this case, the gain may be controlled by the DSP 230 or the like in the electronic apparatus 200.

In other words, in order to suitably suppress the noise generated from the speaker 220, it is preferred that at the power-on of the audio signal amplifier circuit 100 the gain of the variable gain amplifier 70 be increased gradually after the mute state has been deactivated and, at the power-off thereof, the gain be decreased gradually before the mute state is set.

In the embodiment, a description was given of a case where the mute control unit 60 controls the second mute circuit 16 simultaneously with the first mute circuit 20 and the voltage-fixing circuit 50, but the present invention is not limited thereto. For example, if the supply voltage (denoted by Vdd2 here) supplied to the mute control unit 60, the integrator 40, the voltage-fixing circuit 50 or the like in the audio LSI 110 is different from the supply voltage Vdd supplied to the class D amplifier 10, the following control may be performed. In this case, the supply voltage Vdd2 may be started beforehand and the internal circuits, including the mute control unit 60 and the like, in the audio LSI 110 are set to an operable state; the second mute circuit 16 may be set active before the supply voltage Vdd of the class D amplifier is started; and then the first mute circuit 20 and the voltage-fixing circuit 50 may be controlled in synchronism with the rising timing of the supply voltage Vdd of the class D amplifier.

In the present embodiment, a description was given of a case where, of the components used for the audio signal amplifier circuit 100, the audio LSI 110 is integrated on a single semiconductor integrated circuit. However, the embodiment is not limited thereto and the structure may be such that a plurality of LSIs are integrated thereon.

The electronic apparatus 200 equipped with the audio signal amplifier circuit 100 according to the embodiment is not limited to the television set of FIG. 2 described in the embodiment but may be widely applicable to such other devices as CD players, audio amplifiers and so forth.

While the preferred embodiments of the present invention have been described using specific terms, such description is for illustrative purposes only, and it is to be understood that changes and variations may be made without departing from the spirit or scope of the appended claims.

1. An audio signal amplifier circuit, comprising:
a class D amplifier;
an integrator which receives an analog audio signal and an output signal of said class D amplifier and which generates analog voltage in a manner that in an active state a duty ratio of the output signal of said class D amplifier is brought close to a duty ratio defined by the analog audio signal;
a pulse-width modulator which converts the analog voltage outputted from said integrator into a pulse-width modulation signal;
a driver circuit which drives said class D amplifier, based on the pulse-width modulation signal;
a first mute circuit, provided on a path leading to said class D amplifier from said pulse-width modulator, which forcibly turns off said class D amplifier in an active state;
a voltage-fixing circuit which fixes the analog voltage outputted from said integrator in an active state, to a predetermined fixed potential;
a filter which removes a high-frequency component of the output signal of said class D amplifier;
a second mute circuit, provided between an output terminal of said filter and ground, which connects the output terminal of said filter to ground in an active state; and
a mute control unit which controls said integrator, said first mute circuit, said voltage-fixing circuit and said second mute circuit, respectively.

2. An audio signal amplifier circuit according to claim 1, wherein when said audio signal amplifier circuit is started, in a first stage said mute control unit sets said first mute circuit and said second mute circuit active, sets said voltage-fixing circuit active and sets said integrator inactive so as to be set said audio signal amplifier circuit to a mute state, and
subsequently, in a second stage, said mute control unit sets the first mute circuit inactive, then sets said voltage-fixing circuit inactive, sets said integrator active and then sets said second mute circuit inactive so as to terminate the mute state.

3. An audio signal amplifier circuit according to claim 2, wherein in the first stage said mute control unit sets simultaneously the first mute circuit and the second mute circuit active.

4. An audio signal amplifier circuit according to claim 1, wherein when said audio amplifier circuit is stopped, said mute control unit sets said second mute circuit active,
then sets said first mute circuit active, and
then sets said integrator inactive and sets said voltage-fixing circuit active so as to be set said audio signal amplifier circuit to a mute state.

5. An audio signal amplifier circuit according to claim 1, wherein said voltage-fixing circuit and said integrator include integrally:
an operational amplifier in which the analog audio signal is inputted to a first input terminal thereof via a first resistor and a reference voltage is applied to a second input terminal thereof;
a capacitor provided between an output terminal of the operational amplifier and the first input terminal;
a switch and a second resistor provided in series between the output of the operational amplifier and an output terminal of said class D amplifier; and
a third resistor provided between a connection node of the switch and the second resistor and the first input terminal of the operational amplifier,
wherein when the switch is being on, said voltage-fixing circuit and said integrator function as said voltage-fixing circuit; and when the switch is being off, said voltage-fixing circuit and said integrator function as said integrator.

6. An audio signal amplifier circuit according to claim 1, further comprising:
a fourth resistor provided between the output of said class D amplifier and the power supply line; and
a fifth resistor provided between the output terminal of said class D amplifier and ground.

7. An audio signal amplifier circuit according to claim 1, wherein said class D amplifier, said integrator, said pulse-width modulator, said driver circuit, said first mute circuit, said voltage-fixing circuit and said mute control unit are integrated on a single semiconductor substrate, and
wherein said filter and said second mute circuit are provided external to the semiconductor substrate.

8. An audio signal amplifier circuit according to claim 1, wherein said second mute circuit includes:
a first bipolar transistor in which an emitter is connected to the output terminal of said filter and a collector is grounded; and
a second bipolar transistor in which a collector is connected to the output of said filter and an emitter is grounded,
wherein active/inactive is switched by base voltages of the first bipolar transistor and the second bipolar transistor.

9. An audio signal amplifier circuit according to claim 1, further comprising a variable gain amplifier, provided anterior to said integrator, which amplifiers the analog audio signal,
wherein said mute control unit controls gain of said variable gain amplifier.

10. An audio signal amplifier circuit according to claim 9, wherein when said audio signal amplifier circuit is started, in a first stage said mute control unit sets said first mute circuit and said second mute circuit active, sets said voltage-fixing circuit active and sets said integrator inactive and sets the gain of said variable gain amplifier to a minimum value so as to be set said audio signal amplifier circuit to a mute state, and
subsequently, in a second stage, said mute control unit sets the first mute circuit inactive, then sets said voltage-fixing circuit inactive, sets said integrator active, then sets said second mute circuit inactive so as to terminate the mute state, and then increases gradually the gain of said variable gain amplifier.

11. An audio signal amplifier circuit according to claim 9, wherein when said audio signal amplifier circuit is stopped,
said mute control unit decreases gradually the gain of said variable gain amplifier to the minimum value,
then turns said second mute circuit on,
then sets said first mute circuit active, and
then sets said integrator inactive and sets said voltage-fixing circuit active so as to be set said audio signal amplifier circuit to a mute state.

12. An electronic apparatus, comprising:
an audio reproduction unit which outputs an analog audio signal;
an audio signal amplifier circuit, according to claim 1, which amplifies the analog audio signal outputted from said audio reproduction unit; and
an audio output unit driven by said audio signal amplifier.
